(19) United States
(12) Patent Application Publication
(10) Pub. No.: US 2012/0287577 A1
(43) Pub. Date: Nov. 15, 2012

(54) LIQUID COOLING ELEMENT

(75) Inventors: Pertti SEVÄKIVI, Lepsama (FI); Jaani HYYTIÄINEN, Helsinki (FI)

(73) Assignee: ABB Oy, Helsinki (FI)

(21) Appl. No.: 13/451,144

(22) Filed: Apr. 19, 2012

(30) Foreign Application Priority Data
May 13, 2011 (EP) 11166016.3

(51) Int. Cl. F28D 15/00; H05K 7/20

(52) U.S. Cl. 361/702; 165/104.33

(57) ABSTRACT

A cooling element for cooling a plurality of power semiconductor modules including power semiconductor units including a plate made of thermally conductive material. The plate includes channels for carrying a flow of a cooling liquid. The channels include a main supply channel converging in a direction of the flow of the liquid, a main discharge channel diverging in the direction of the flow of the liquid, a plurality of supply channel branches branching from the main input channel, a plurality of discharge channel branches merging to the main discharge channel, and a plurality of power semiconductor unit cooling channels connecting the supply channel branches and the discharge channel branches. Each power semiconductor unit cooling channel is arranged to cool one power semiconductor unit. The plate includes openings for thermally separating the power semiconductor modules from each other.

### RELATED APPLICATION(S)

This application claims priority under 35 U.S.C. §119 to European Patent Application No. 11166016.3 filed in Europe on May 13, 2011, the entire content of which is hereby incorporated by reference in its entirety.

### FIELD

The present disclosure relates to cooling of power semiconductors and for example, to liquid cooling of power semiconductor modules.

### BACKGROUND INFORMATION

Semiconductors can produce heat and can be desirable to keep their temperature within a given range by cooling.

There are many approaches for cooling a semiconductor, for example, by using a cooling element which conducts heat away from the semiconductors. The cooling element can be, for example, a heat sink cooled by air flow. The flow of air can be gravitational or produced mechanically.

Air-cooled heat sinks can be sufficient for applications of lower power. As a maximum power transferred rises, the amount of dissipated heat can also rise. Air has limited thermal capacity, and therefore, an air cooling element that can provide sufficient cooling capacity can become so bulky and expensive that air cooling can be impractical.

Some liquids, such as, for example, water, have higher thermal capacity than air. They can transfer heat from the semiconductors more efficiently than air. However, liquid cooling can require a circulatory system, which can be more complex than an open system like air cooling. Care may have to be taken in order to avoid leaks because the liquid may be electrically conductive and can cause short circuits in the arrangement to be cooled.

FIG. 1 illustrates a liquid cooling arrangement for three power semiconductor modules arranged in parallel on a cooling plate 10. The cooling plate 10 is made of a thermally conducting material. The semiconductor modules can include a plurality of power semiconductor units. A semiconductor unit can include, for example, a diode, a transistor, or both. A power semiconductor unit can include, an IGBT in parallel with a diode, and a power semiconductor module can include one or more of these power semiconductor units.

The cooling plate 10 includes channels in which the cooling liquid runs. A main supply channel 11 branches into a plurality of cooling channels 12. In FIG. 1, two cooling channels 12 run under each module, for cooling the power semiconductor units. The cooling channels 12 then join to a main discharge channel 13. The channels 11, 12, and 13 can be produced into the cooling plate 10, for example, by drilling and plugging some of the drill hole entrances.

By using liquid cooling, the semiconductor modules can be cooled more efficiently than by using air cooling. However, the heat distribution can be uneven. This can be problematic because the hottest point of a semiconductor module determines the maximum load on the module. Uneven heat distribution can also cause mechanical strain to the power semiconductor modules.

### SUMMARY

A cooling element is disclosed for cooling at least one power semiconductor module including power semiconductor units, the cooling element comprising a plate made of thermally conductive material, wherein the plate is configured for thermal connection to power semiconductor modules and includes channels for carrying a flow of a cooling liquid and openings for thermally separating the power semiconductor modules from each other; wherein the channels comprise: a main supply channel converging in the direction of a flow of a liquid; a main discharge channel diverging in the direction of the flow of the liquid; a plurality of supply channel branches branching from the main supply channel; a plurality of discharge channel branches merging to the main discharge channel; and a plurality of power semiconductor unit cooling channels connecting the supply channel branches and the discharge channel branches wherein each power semiconductor unit cooling channel is arranged to cool one power semiconductor unit.

### BRIEF DESCRIPTION OF THE DRAWINGS

In the following, the disclosure will be described in greater detail by means of exemplary embodiments with reference to the attached drawings, in which:

FIG. 1 illustrates a liquid cooling arrangement;

FIGS. 2a, 2b, and 2c illustrate an exemplary embodiment of the present disclosure; and

FIGS. 3a and 3b illustrate an isometric view of an exemplary cooling plate according to the present disclosure.

### DETAILED DESCRIPTION

A cooling element according to an exemplary embodiment of the disclosure includes a cooling plate which has channels for carrying a flow of a cooling liquid. A main supply channel for the cooling liquid breaks up into supply channel branches. These branches further divide into cooling channels. The cooling plate can have a separate cooling channel or channels under each power semiconductor unit. The cooling plate can have openings between the power semiconductor modules so that they will not heat each other.

The cooling channels under the power semiconductor units can be parallel to each other, and therefore, arranged so that cooling of one power semiconductor unit does not affect cooling of another power semiconductor unit. The cooling channels recombine into discharge channel branches which, in turn, recombine into a main discharge channel.

To enhance exchange of heat, the channels and channel branches can be provided with fins. The main supply channel can be formed to converge in a direction of the liquid flow, and the main discharge channel can be formed to diverge in the direction of the liquid flow. In this manner, equal flow in the supply channel branches and the discharge channels branches can be achieved. The supply channel branches and the discharge channel branches can be formed converging and diverging in order to achieve even flow in the cooling channels.

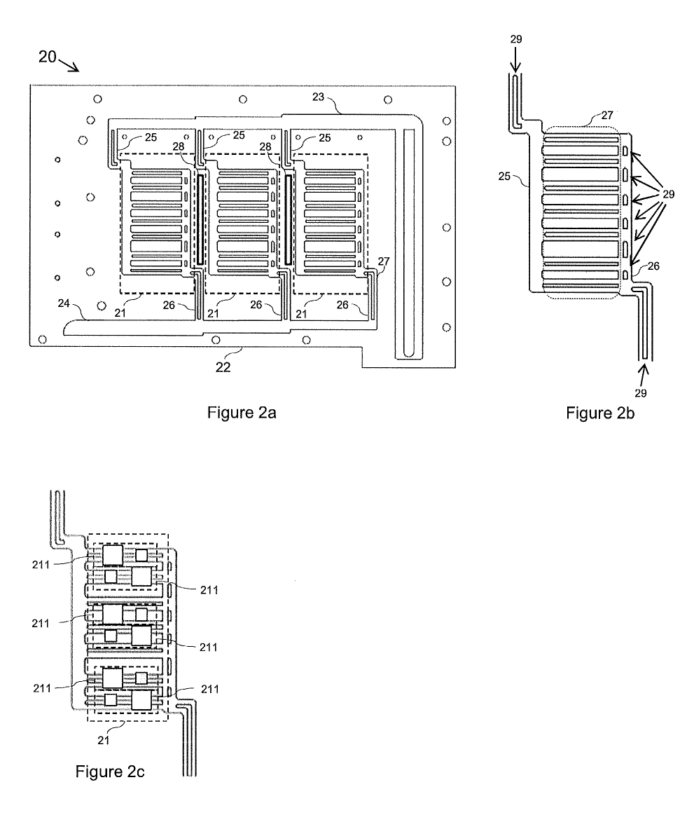

FIGS. 2a, 2b, and 2c illustrate an exemplary embodiment according to the present disclosure. A cooling element 20 for cooling a plurality of power semiconductor modules 21 including power semiconductor units includes a plate 22 made of thermally conductive material. In FIG. 2a, three modules 21 are used. FIG. 2b shows details for cooling of one of the modules 21 of FIG. 2a. FIG. 2c illustrates an exemplary positioning of power semiconductor units 211 inside a power semiconductor module 21.

A power semiconductor unit can, for example, include a diode, a transistor, or both. The power semiconductor units can include an IGBT and a diode. In FIG. 2c, each power semiconductor unit 211 includes a diode (smaller square) and an IGBT (larger square). Other semiconductors and/or configurations of power semiconductor units and modules can also be used.

The cooling plate 22 is adapted to be thermally connected to the power semiconductor modules 21. In FIG. 2a, the power semiconductor modules 21 are arranged next to each other on the cooling plate 22. The modules 21 can be attached to the cooling plate 22, for example, by screws to ensure adequate thermal connection.

The cooling plate 22 includes channels for carrying a flow of a cooling liquid. The channels form a circulatory system. The channels include a main supply channel 23 into which the cooling liquid can be fed, and a main discharge channel 24 from which the cooling liquid heated by the power semiconductor units can be discarded. The cooling plate 22 with channels can be, for example, machined from a block and sealed with a close-fitting lid.

The main supply channel 23 divides into a plurality of supply channel branches 25 branching from the main input channel 23. The main discharge channel 24 is divided into branches in a similar manner. In FIG. 2a, a plurality of discharge channel branches 26 merge to the main discharge channel 24.

A plurality of power semiconductor unit cooling channels 27 connects the supply channel branches 25 and the discharge channel branches 26, as illustrated in FIG. 2b. Each power semiconductor unit cooling channel 27 can be arranged to cool one power semiconductor unit.

However, a power semiconductor unit can have more than one cooling channel 27 cooling the power semiconductor unit. The number of cooling channels 27 per semiconductor unit can depend on the configuration of the power semiconductor module 21. FIG. 2c shows two cooling channels per power semiconductor unit 211.

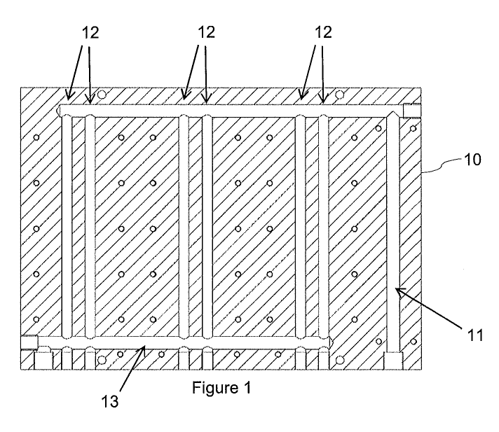

The cooling channels 27 can be parallel to each other. In contrast to the cooling element of FIG. 1, cooling of one power semiconductor unit may not affect cooling of another power semiconductor unit. Each power semiconductor unit in a power semiconductor module 21 can receive equally cool cooling liquid, and a temperature difference between the power semiconductor units can thus be minimized. As a result, the power semiconductor module 21 can withstand higher currents. As the heat produced by the module 21 can be distributed evenly, the power semiconductor module 21 can also experience less mechanical strain.

In FIG. 1, the main supply channel 11 and the main discharge channel 13 both have cross sections which can be uniform in respect of their lengths. This can cause the cooling channels 12 to have uneven flows. The amount of flowing liquid can be reduced as cooling channels branch off the main supply channel 11.

This can allow higher speed of the flow in the following cooling channels. At the same time, flows in cooling channels farther away from a discharge channel exit point can be slowed down by cooling channels nearer the exit point.

In the cooling element according to an exemplary embodiment of the disclosure, the main supply channel can be formed to converge in the direction of the flow of the liquid, and the main discharge channel can be formed to diverge in the direction of the flow of the liquid, as in FIG. 2a. More equal flow (and pressure) in the supply channel branches and the discharge channel branches can thus be achieved.

The supply channel branches can also be arranged to converge in the direction of the flow of the liquid and the discharge channel branches to diverge in the direction of the flow of the liquid.

To enhance exchange of heat, the channels can be provided with fins 29, as in FIG. 2b, thus producing turbulence in the flow of the liquid and increasing the surface area between the cooling liquid and walls of the channels.

When a cooling plate is made of a thermally conducting material, heat produced by a power semiconductor module can cause a rise in the temperature in another power semiconductor module. In order to avoid exchange of heat between the power semiconductor modules, the plate can include openings 28 for thermally separating the power semiconductor modules from each other, as in FIG. 2a.

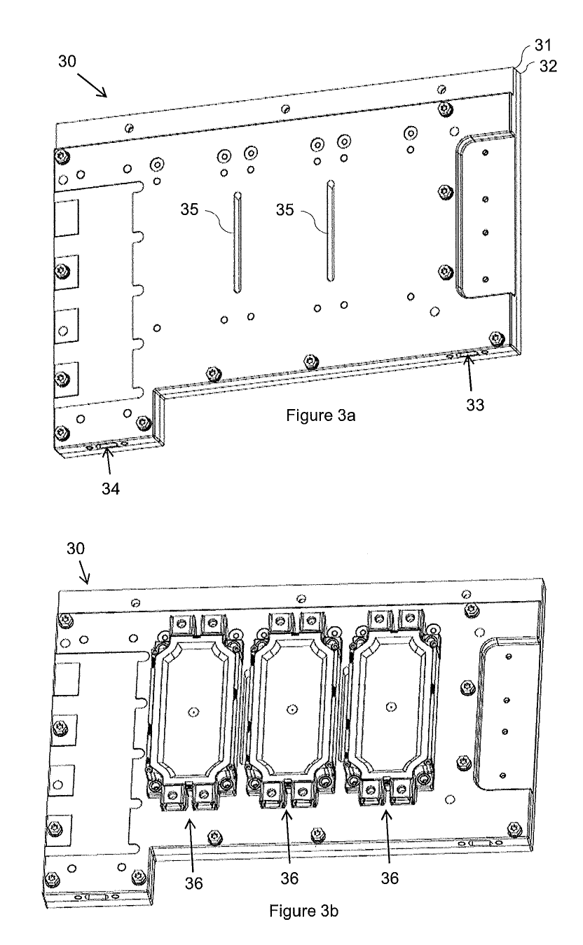

FIG. 3a illustrates an isometric view of an exemplary cooling plate 30 with thermal separation of power semiconductor units. The cooling plate 30 can be assembled from a top side metal plate 31 and a bottom side metal plate 32 which can be fastened together by screws. The metal plates 31 and 32 can be made of, for example, aluminium. However, other thermally conductive materials, for example copper, can also be used.

The top side metal plate 31 includes channels for carrying a flow of a cooling liquid. The channels are sealed with the bottom metal plate 32. An entry opening 33 for a main supply channel can be seen on bottom left corner of FIG. 3a. An exit opening 34 for a main discharge channel can be found in the bottom right corner of FIG. 3a.

The top side metal plate 31 can be configured to accommodate three power semiconductor modules. Two openings 35 in the top side metal plate 31 thermally separate three power semiconductor modules. In FIG. 3a, the openings 35 protrude into some depth of the plate. However, in some embodiments, the openings can go all the way through the cooling plate.

FIG. 3b illustrates an isometric view of the same cooling plate 30 with three power semiconductor modules 36 mounted on it. Without the openings 35, the power semiconductor module in the middle in FIG. 3b may operate at a higher temperature than the power semiconductor modules on the sides because the modules on the sides can heat up the module in the middle.

In some embodiments, the supply channel branches can originate from the main supply channel at the same point, and/or the discharge channel branches can merge into the main discharge channel at the same point. Alternatively, the main supply channel can be provided with dividing walls separating liquid flows of the supply channel branches, and the main discharge channel can be provided with dividing walls separating liquid flows of the discharge channel branches. In both cases, the flows of the branches would be separate from each other. Thus, the flow speed would be approximately the same for each branch.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A cooling element for cooling at least one power semiconductor module including power semiconductor units, the cooling element comprising:
a plate made of thermally conductive material, wherein the plate is configured for thermal connection to power semiconductor modules and includes channels for carrying a flow of a cooling liquid and openings for thermally separating the power semiconductor modules from each other; and
wherein the channels comprise:
a main supply channel converging in a direction of a flow of the cooling liquid;
a main discharge channel diverging in the direction of the flow of the cooling liquid;
a plurality of supply channel branches branching from the main supply channel;
a plurality of discharge channel branches merging to the main discharge channel; and
a plurality of power semiconductor unit cooling channels connecting the supply channel branches and the discharge channel branches wherein each power semiconductor unit cooling channel is arranged to cool one power semiconductor unit.

2. A cooling element according to claim 1, comprising:
fins provided for the channels for producing turbulence in the flow of the liquid.

3. A cooling element according to claim 1, comprising:
dividing walls provided for the main supply channel for separating liquid flows of the supply channel branches.

4. A cooling element according to claim 1, comprising:
dividing walls for the main discharge channel for separating liquid flows of the discharge channel branches.

5. A cooling element according to claim 1, wherein the supply channel branches converge in the direction of the flow of the cooling liquid and the discharge channel branches diverge in the direction of the flow of the cooling liquid.

6. A cooling element according to claim 1, comprising:
at least one power semiconductor module arranged on the plate.

7. A power semiconductor module in combination with the cooling element of claim 1.
